(19) United States
(12) Patent Application Publication
(10) Pub. No.: US 2008/0053695 A1
(43) Pub. Date: Mar. 6, 2008

(54) Electromagnetic wave absorber and method of constructing the same

(76) Inventor: Jae-Chul Choi, Seoul (KR)

Correspondence Address: HEDMAN & COSTIGAN P.C., 1185 AVENUE OF THE AMERICAS, NEW YORK, NY, 10036, US

(21) Appl. No.: 11/895,166

(22) Filed: Aug. 23, 2007

(30) Foreign Application Priority Data
Sep. 5, 2006 (KR) 10-2006-0085043

(51) Int. Cl. H05K 9/00

(52) U.S. Cl. 174/390

(57) ABSTRACT

Disclosed is an electromagnetic wave absorber, which is obtained by attaching a three-dimensional open-cell type metal porous body to an electromagnetic wave-reflecting surface and filling the pores of the three-dimensional open-cell type metal porous body with an electromagnetic wave-absorbing material.

### BACKGROUND OF THE INVENTION

1. Field of the Invention

The present invention relates generally to an electromagnetic wave absorber and a method of constructing the same, and, more particularly, to a manufacture of an electromagnetic wave absorber, which is thin in thickness and has a wider usable frequency range.

2. Description of the Related Art

In recent years, while various electronic devices are required to accelerate the speed-up thereof and to greatly increase the usable frequency range thereof to high frequencies, unnecessary noise is radiated. Furthermore, according to the trend of digitizing of electronic and communication devices, immunity (noise resistance) is decreased, worsening the internal noise environment of the electronic device, undesirably causing the malfunction of the electronic device due to electromagnetic interference (EMI).

Electromagnetic waves reflected from iron structures around radar receivers for ships or aircraft are received by the radar to thus generate ghost images, undesirably impeding the safe travel of ships or aircraft. In addition, there are cases in which military aircraft, tanks, or warships may be detected by the radar of the hostile army, making it impossible to carry out military operations.

In order to solve the above problems, an electromagnetic wave absorber has been used. A conventional electromagnetic wave absorber, as illustrated in FIG. 10, includes an electromagnetic wave-absorbing material A and a metal reflective sheet M attached to the back surface of the electromagnetic wave-absorbing material A in the direction of incidence of electromagnetic waves. The above electromagnetic wave absorber functions in a manner such that the electromagnetic waves are incident on the electromagnetic wave-absorbing material A, after which the reflection waves between the metal reflective sheet M and the electromagnetic wave-absorbing material and the reflection waves reflected from the surface (front surface) of the electromagnetic wave-absorbing material A are controlled to have a phase difference of 180°, thereby canceling the reflection waves, resulting in the absorption of the electromagnetic waves.

The electromagnetic wave-absorbing material A may be a foamed rubber or plastic body coated with a conduction loss material such as carbon black or graphite, or may be formed in a sheet (which is typically referred to as a “rubber ferrite sheet”) in which a magnetic loss material such as MnZn ferrite is dispersed in a binder (rubber or plastic), or in a paste phase, in which the magnetic loss material is dispersed in a paint vehicle. Particularly useful as the electromagnetic loss material in the electromagnetic wave-absorbing material A is ferrite, which is the magnetic loss material. The ferrite shows a phenomenon in which the loss is increased due to resonance accompanied by gyro magnetic movement or magnetic wall movement in a predetermined frequency range. When the electromagnetic waves having the predetermined frequency range, at which the loss is increased, are incident, such electromagnetic waves may be absorbed with the conversion of electromagnetic wave energy into thermal energy due to resonance. In the case of the rubber ferrite sheet, however, when the electromagnetic waves are absorbed at the center frequency of 2.45 GHz, the rubber ferrite sheet suffers because it is as thick as 10 mm, and is thus too heavy, and the effectively usable frequency range (decay range above the minimum of −10 dB) is too narrow, making it difficult to use the rubber ferrite sheet.

Upon resonance absorption of the electromagnetic waves using ferrite, in the case where a high-frequency magnetic field is applied, when the magnetic flux is passed through ferrite in a state in which portions of ferrite dispersed in the binder are not in contact with each other, magnetic permeability is maintained and electric resistance is greatly increased. However, when ferrite portions are connected to each other, electric resistance is decreased and thus current is induced in the ferrite, thereby generating eddy-current loss, undesirably decreasing magnetic permeability, resulting in deteriorated electromagnetic wave-absorbing performance. As such, in order to increase electromagnetic wave-absorbing performance, the thickness of the ferrite sheet must be further increased, disadvantageously limiting the use thereof.

For example, in the case of an F-17 Stealth fighter-bomber, USA, when it is designed to have a wider frequency range for stealth using the rubber ferrite sheet, the ferrite sheet is required to be thick, and is thus becomes heavy. Hence, the intermediate- or long-range radar stealth aircraft uses structural stealth material, whereas only the short-range radar stealth aircraft may have the rubber ferrite sheet attached thereto, or ferrite electromagnetic wave-absorbing material applied thereon in the form of paint.

With the goal of solving the problems of the electromagnetic wave absorber, a lot of effort has been made. In this regard, U.S. Pat. No. 6,919,387 discloses an electromagnetic wave absorber, a method of manufacturing the same, and an appliance using the same, and U.S. Pat. No. 6,670,546 discloses a radio wave absorber.

In the former electromagnetic wave absorber, the magnetic metal particles were coated with ceramic to thus improve electromagnetic wave-absorbing properties in the high frequency range above 1 GHz. In the latter radio wave absorber, the specific dielectric constant of the magnetic layer was controlled, thereby obtaining a radio wave absorber as thin as 1 mm and having good electromagnetic wave-absorbing properties in the high frequency range of 1˜3 GHz.

In the former electromagnetic wave absorber and the latter radio wave absorber, mentioned above, the magnetic permeability and/or dielectric constant of the electromagnetic wave loss material are controlled, thereby slightly improving the thickness and electromagnetic wave-absorbing properties of the absorber. However, because the electromagnetic wave-absorbing method depends on the manner in which the reflection waves between the electromagnetic wave-absorbing material and the metal reflective sheet and the reflection waves reflected from the surface of the electromagnetic wave-absorbing material are controlled to have a phase difference of 180°, thus canceling the reflection waves, as illustrated in FIG. 10, the electromagnetic wave-absorbing properties are not good, whereby the effectively usable frequency range is narrow.

### SUMMARY OF THE INVENTION

Accordingly, the present invention has been made keeping in mind the above problems occurring in the prior art, and an aspect of the present invention is to provide an electromagnetic wave absorber, which is manufactured to be thin and to have a wider usable frequency range through a great improvement in the electromagnetic wave-absorbing method, and a method of constructing the electromagnetic wave absorber, in which the electromagnetic wave absorber may be simply constructed at a construction site.

According to the present invention, in order to accomplish the above aspect, an electromagnetic wave absorber may include a three-dimensional open-cell type metal porous body, and an electromagnetic wave-absorbing material loaded in the pores of the three-dimensional open-cell type metal porous body, such that the incident electromagnetic waves and the reflected electromagnetic waves are absorbed by the electromagnetic wave-absorbing material while being reflected many times (diffuse reflection).

According to the present invention, a method of constructing the electromagnetic wave absorber may include attaching a three-dimensional open-cell type metal porous body to an electromagnetic wave-reflecting surface, and filling the pores of the three-dimensional open-cell type metal porous body with an electromagnetic wave-absorbing material using a filler.

The three-dimensional open-cell type metal porous body has a number of PPI (Pores Per Inch) of 5˜50. When the PPI is less than 5, the diffuse reflection of the incident electromagnetic waves and the reflected electromagnetic waves becomes poor, undesirably decreasing electromagnetic wave-absorbing performance. On the other hand, when the PPI exceeds 50, the amount of the electromagnetic waves incident on the inside of the metal porous body is drastically decreased, and the reflection thereof is increased, undesirably decreasing the electromagnetic wave-absorbing performance.

The electromagnetic wave-absorbing material is obtained by dispersing the electromagnetic wave loss material, for example, a conduction loss material, a dielectric loss material, a magnetic loss material, and an eddy-current loss material, in a binder. As such, the binder includes known rubber, or inorganic or organic material.

In the present invention, because the electromagnetic wave-absorbing material is loaded in the three-dimensional open-cell type metal porous body, as mentioned above, the electromagnetic waves, which are incident on the pores of the three-dimensional open-cell type metal porous body, are converted into thermal energy by the electromagnetic wave-absorbing material while being reflected many times (diffuse reflection), thus decaying them. Further, when the electromagnetic waves are reflected from the surface of the porous body, they are converted into thermal energy by the electromagnetic wave-absorbing material while being subjected again to diffuse reflection from the pores of the porous body, thus decaying them, thereby greatly improving the electromagnetic wave-absorbing performance. Ultimately, the electromagnetic wave absorber may be manufactured to be thin and to have a wider usable frequency range, and furthermore, may be simply and inexpensively manufactured and constructed.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view illustrating an electromagnetic wave absorber according to a first embodiment of the present invention;

FIG. 2 is a sectional view illustrating the electromagnetic wave absorber according to the first embodiment of the present invention;

FIG. 3 is a perspective view illustrating the three-dimensional open-cell type metal porous body of the electromagnetic wave absorber according to the first embodiment of the present invention;

FIG. 4 is a perspective view illustrating the three-dimensional open-cell type metal porous body of an electromagnetic wave absorber according to a second embodiment of the present invention;

FIG. 5 is a sectional view of FIG. 4;

FIG. 6 is a sectional view illustrating an electromagnetic wave absorber according to a third embodiment of the present invention;

FIGS. 7 to 9 are views illustrating the electromagnetic wave-absorbing properties of the electromagnetic wave absorbers according to the embodiments of the present invention; and

FIG. 10 is a sectional view illustrating a conventional electromagnetic wave absorber.

### DESCRIPTION OF THE PREFERRED EMBODIMENTS

Reference now should be made to the drawings, in which the same reference numerals are used throughout the different drawings to designate the same or similar components.

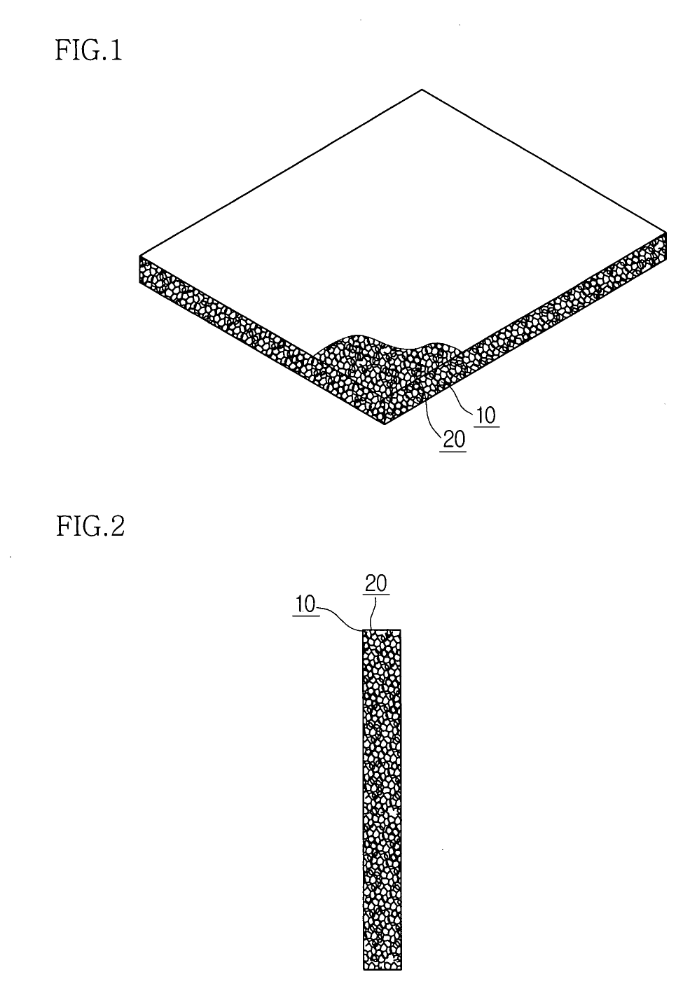

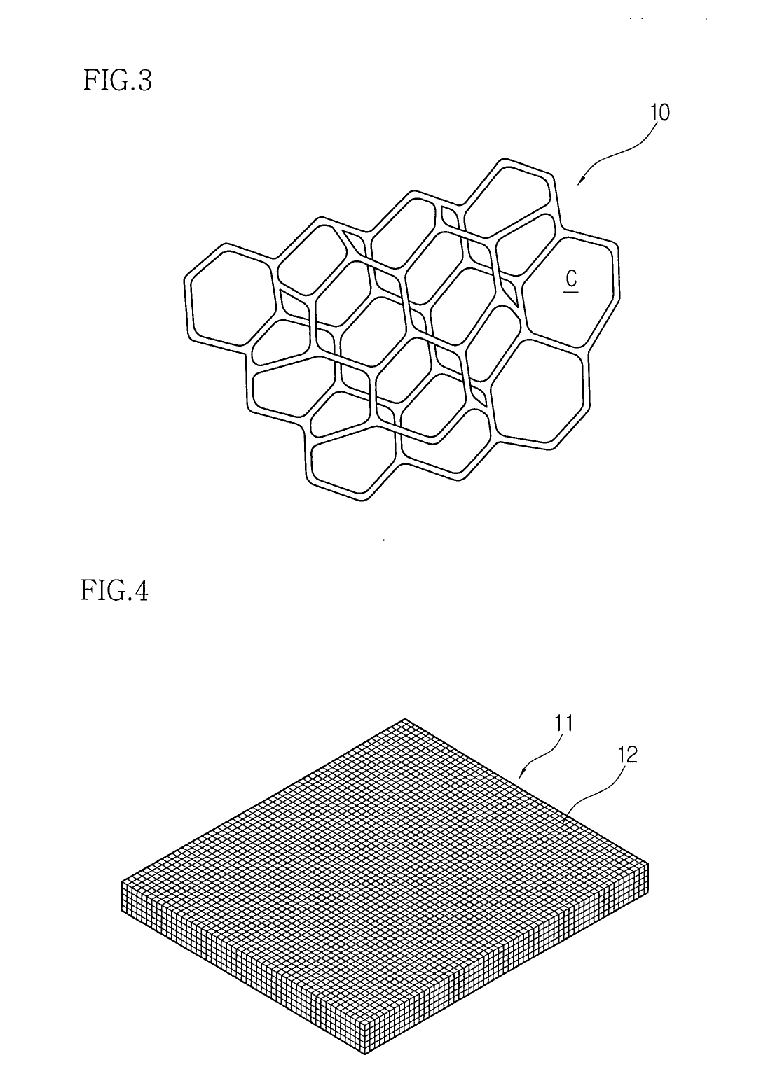

FIG. 1 is a perspective view illustrating an electromagnetic wave absorber according to a first embodiment of the present invention, FIG. 2 is a sectional view illustrating the electromagnetic wave absorber according to the first embodiment of the present invention, and FIG. 3 is a perspective view illustrating the three-dimensional open-cell type metal porous body of the electromagnetic wave absorber according to the first embodiment of the present invention, in which reference numeral 10 designates the three-dimensional open-cell type metal porous body, and reference numeral 20 designates the electromagnetic wave-absorbing material loaded in the open-cell type metal porous body.

The three-dimensional open-cell type metal porous body 10 may include any one selected from among nonmagnetic metals, including gold, platinum, silver, copper, nickel, zinc, aluminum, tin, stainless steel and titanium, or alloys thereof, subjected to a known method of manufacturing a three-dimensional open-cell type metal porous body to thus form a plurality of pores C, or any one selected from among mats, pads, and nonwoven fabrics of nonmagnetic metal fiber.

In addition, the three-dimensional open-cell type metal porous body 10 may include any one selected from among mats, pads, and nonwoven fabrics of natural fiber, synthetic fiber, inorganic fiber, ceramic fiber, and glass fiber, each of which has the nonmagnetic metal film formed thereon and has the plurality of pores C, or any one selected from among foamed bodies of rubber, synthetic resin, natural resin, ceramic and glass, each of which is coated with the nonmagnetic metal layer. The three-dimensional open-cell type metal porous body 10 may have a PPI of 5˜50.

The three-dimensional open-cell type metal porous body 10 is filled with a filler, a molding means, or a rolling means, with the electromagnetic wave-absorbing material 20 obtained by dispersing one or more selected from among electromagnetic wave loss materials, including conduction loss materials, dielectric loss materials, magnetic loss materials, and eddy-current loss materials in a binder, thus manufacturing the electromagnetic wave absorber. In the filling process, a coating film may be formed on either or both surfaces of the three-dimensional open-cell type metal porous body 10 to thus cover the three-dimensional open-cell type metal porous body 10 and realize a beautiful surface appearance. The electromagnetic wave absorber may be provided in the form of a sheet, a panel, or a block.

The conduction loss material includes one or more selected from among carbon black, acetylene black, graphite, and silicon carbide powder, and the dielectric loss material includes one or more selected from among alumina-, barium titanate-, lead titanate-, magnesium titanate-, and lithium zirconium titanate-based materials. The magnetic loss material includes one or more selected from among soft magnetic oxide materials (Me Fe₂O₄), soft magnetic metal materials (Fe, Co, Ni), and hexagonal magnetic materials (M Fe₁₂O₁₉). The eddy-current loss material includes one or more selected from among carbonyl iron fiber, carbon fiber, and silicon carbide fiber, each of which has a film of an insulator, such as alumina (Al₂O₃), silica (SiO₂) or hollow silica, formed thereon, and is powdered, or alternatively one or more selected from among natural fiber, synthetic fiber, glass fiber, inorganic fiber, and ceramic fiber, each of which has a nonmagnetic metal layer of any one selected from among nonmagnetic metals, including tin, aluminum, silver, gold, platinum and copper, formed on the surface thereof, and is powdered. In the conduction loss material, the dielectric loss material, the magnetic loss material and the eddy-current loss material, fiber powder having a surface coated with an insulator such as alumina or silica, rather than the fiber powder having the insulator film formed thereon, may be used.

The binder includes rubber, natural resin, synthetic resin, glass, and ceramic, and is specifically exemplified by silica gel, cement, polyester resin, acryl resin, epoxy resin, polyurethane resin, silicone resin, chloroprene rubber, and polyvinylchloride.

When the electromagnetic wave loss material is dispersed in the binder, 3˜85 wt % of the electromagnetic wave loss material may be mixed with 15˜97 wt % of the binder.

Further, the electromagnetic wave loss material 20 may be coated with the insulator, such as alumina, silica, aluminum hydroxide, or hollow silica. When the electromagnetic wave loss material is dispersed in the binder, the insulator may be added, to thus increase the electric resistivity of the electromagnetic wave loss material, thereby decreasing the eddy-current loss and assuring high magnetic permeability in the high frequency range, resulting in improved electromagnetic wave-absorbing properties.

When the electromagnetic wave loss material is coated with the insulator, or when the electromagnetic wave loss material is added with the insulator upon dispersion in the binder, the electromagnetic wave loss material may be used in an amount of 3˜75 wt %, the binder may be used in an amount of 15˜96 wt %, and the insulator may be used in an amount of 1˜45 wt %.

According to the first embodiment of the present invention, the electromagnetic wave absorber is obtained in a manner such that the three-dimensional open-cell type metal porous body 10 is placed in a mold, the pores C of the open-cell type metal porous body 10 are filled, using a filler, with the electromagnetic wave-absorbing material 20, formed by dispersing the electromagnetic wave loss material in the binder, dispersing the electromagnetic wave loss material coated with the insulator in the binder, or adding the electromagnetic wave loss material with the insulator when it is dispersed in the binder, and then drying is conducted. Alternatively, the electromagnetic wave absorber may be manufactured by placing the three-dimensional open-cell type metal porous body 10 on a conveyor, placing the electromagnetic wave-absorbing material 20, which is discharged from a dispenser, on the upper surface of the three-dimensional open-cell type metal porous body 10, conducting roll pass to load the electromagnetic wave-absorbing material 20 in the pores C of the three-dimensional open-cell type metal porous body 10, and then conducting drying.

According to the first embodiment, when the electromagnetic wave absorber is attached to the reflecting surface through bonding, electromagnetic waves are incident on the pores C of the three-dimensional open-cell type metal porous body 10 to thus be converted into thermal energy by the electromagnetic wave-absorbing material 20 while being subjected to diffuse reflection, therefore decaying them. Further, when the electromagnetic waves, reflected from the electromagnetic wave-reflecting surface, are reflected from the front surface (opposite the direction of incidence) of the electromagnetic wave absorber, they are converted into thermal energy by the electromagnetic wave-absorbing material 20 while being subjected again to diffuse reflection from the pores C of the porous body, thus decaying them, thereby greatly improving the electromagnetic wave-absorbing performance. Consequently, the electromagnetic wave absorber may be manufactured to be thin and to have a wider usable frequency range.

FIG. 4 is a perspective view illustrating the three-dimensional open-cell type metal porous body of an electromagnetic wave absorber according to a second embodiment of the present invention, and FIG. 5 is a sectional view of the three-dimensional open-cell type metal porous body of FIG. 4, which is different from the three-dimensional open-cell type metal porous body according to the first embodiment.

According to the second embodiment, the three-dimensional open-cell type metal porous body 11 may be formed by laminating a plurality of nets composed of nonmagnetic metal and filling the nonmagnetic metal net laminate 12 thus obtained with the same electromagnetic wave-absorbing material 20 as in the first embodiment using a filler.

According to the second embodiment, because the three-dimensional open-cell type metal porous body 11 is formed by laminating the nonmagnetic metal nets, the manufacturing cost thereof may be drastically decreased.

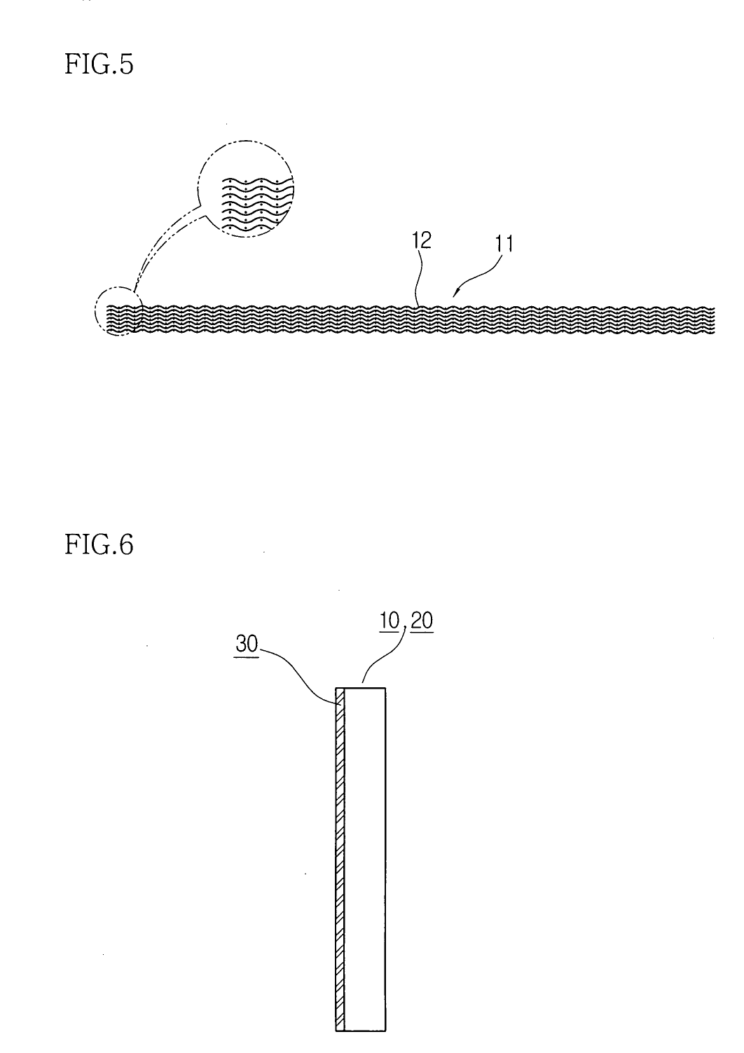

FIG. 6 is a sectional view illustrating an electromagnetic wave absorber according to a third embodiment of the present invention, having a dielectric layer 30 formed on either or both surfaces thereof, unlike the first embodiment. Accordingly, the impedance of the electromagnetic wave incident surface may be based on spatial impedance, thus inhibiting reflections between the media and facilitating the matching of the phases of the reflection waves.

The dielectric layer 30 may be formed using a dielectric loss material among the electromagnetic wave loss materials according to the first embodiment.

A better understanding of the present invention may be obtained in light of the following examples, which are set forth to illustrate, but are not to be construed to limit the present invention.

### EXAMPLE 1

A three-dimensional open-cell type aluminum porous body having a thickness of 3.5 mm and PPI of 30 (available from Hittite Co. Ltd.) was placed in a mold, after which the pores of the aluminum porous body were filled, using a filler, with an electromagnetic wave-absorbing material obtained by dispersing 85 wt % of MnZn ferrite powder (magnetic permeability of 8000, particle size of 3 μm, available from ISU Ceramics) in 15 wt % of two-component epoxy resin (the ratio of main agent to curing agent=2:1, available from Donghae Chemical Co. Ltd.) using a vacuum mixer, followed by conducting drying at room temperature, thus manufacturing an electromagnetic wave absorber 4 mm thick.

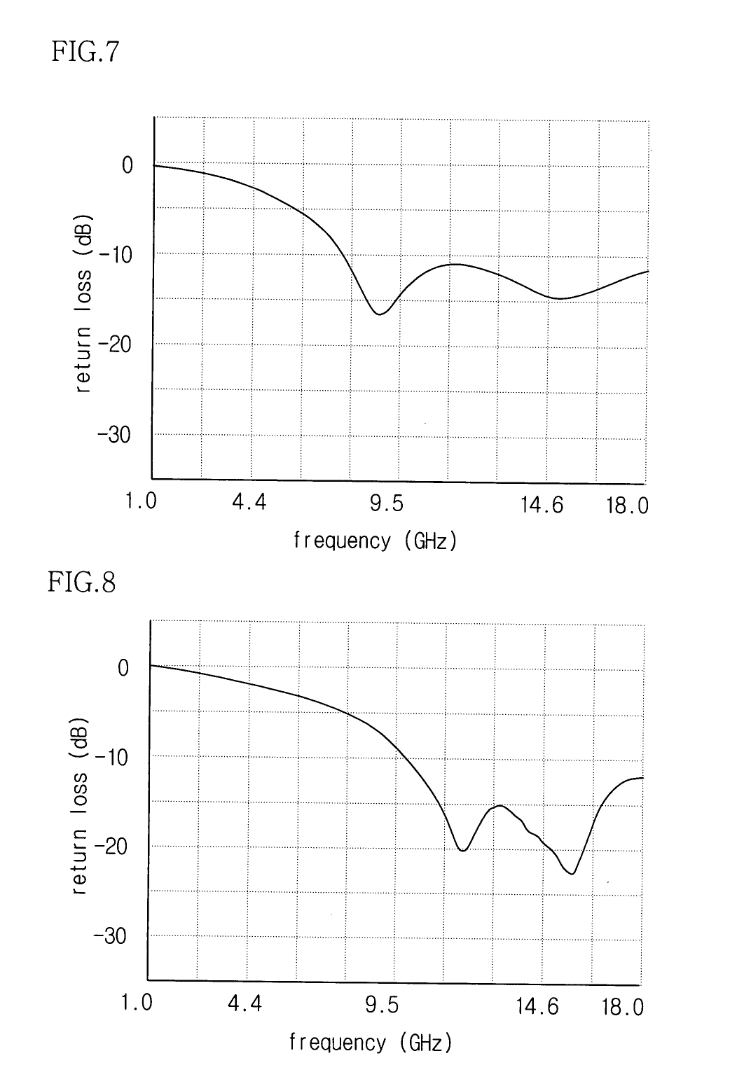

The electromagnetic wave-absorbing performance of the electromagnetic wave absorber was measured through a transmission line method. The results are shown in FIG. 7. As is apparent from this drawing, the effectively usable frequency range, having a return loss ranging from −10 dB to −15 dB (90˜98%), was obtained in the frequency range of 7˜18 GHz.

### EXAMPLE 2

The same three-dimensional open-cell type aluminum porous body as in Example 1, with the exception that it had a thickness of 2.5 mm and a PPI of 40, was attached to an acryl resin sheet, after which the pores of the aluminum porous body were filled, using a filler, with an electromagnetic wave-absorbing material obtained by dispersing 78 wt % of carbonyl iron powder (particle size of 5 μm, flake type, available from ChangSung Co. Ltd.) in 22 wt % of two-component epoxy resin (the same as in Example 1), followed by conducting drying at room temperature, thus manufacturing an electromagnetic wave absorber 3 mm thick.

The performance of the electromagnetic wave absorber was measured through the same method as in Example 1. The results are shown in FIG. 8. As is apparent from this drawing, the effectively usable frequency range, having a return loss ranging from −6 dB to −20 dB (75˜99%), was obtained in the frequency range of 7˜18 GHz.

### EXAMPLE 3

A three-dimensional open-cell type nickel porous body having a thickness of 4.5 mm and a PPI of 20 was formed to have a cylindrical shape, a barium titanate powder sheet 1 mm thick (particle size of 1 μm, available from Sukgyung Co. Ltd.) was attached to the outer surface of the cylindrical nickel porous body, an electromagnetic wave-absorbing material, obtained by mixing 75 wt % of Sendust powder (particle size of 1 μm, available from ChangSung Co. Ltd.) with 25 wt % of two-component epoxy resin (the same as in Example 1) using a vacuum mixer was charged into a filler to thus be loaded in the pores of the nickel porous body, and then drying was conducted at room temperature, thus manufacturing a cylindrical electromagnetic wave absorber 6 mm thick having a dielectric layer.

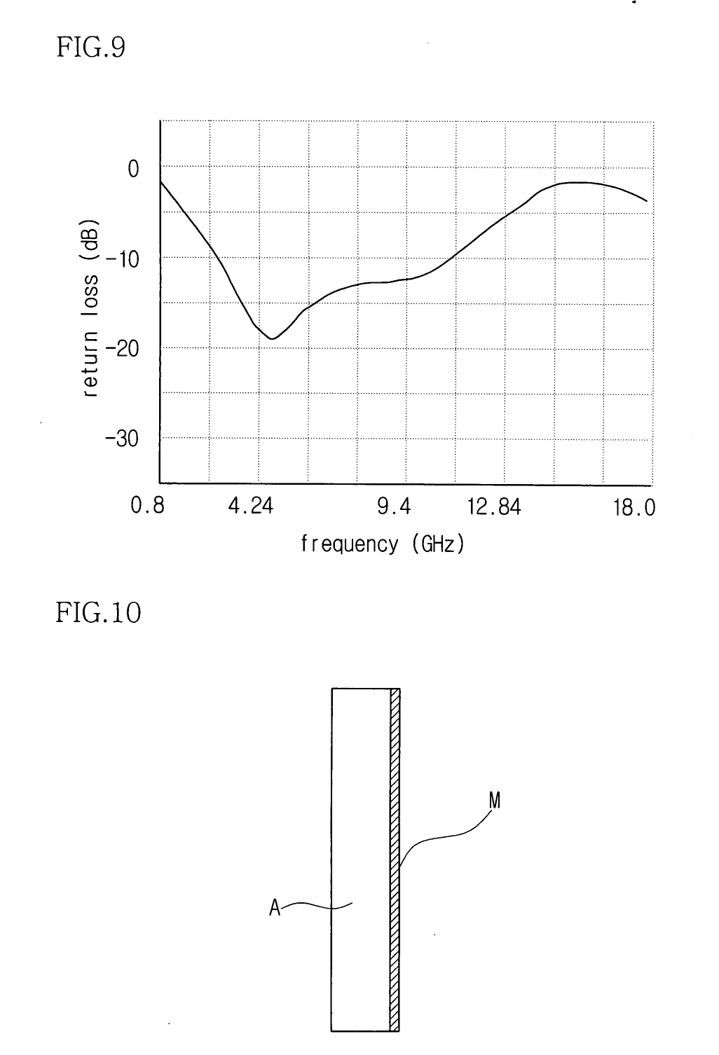

The performance of the cylindrical electromagnetic wave absorber having the dielectric layer was measured through the same method as in Example 1. The results are shown in FIG. 9. As is apparent from this drawing, the electromagnetic wave-absorbing performance, having a return loss ranging from −10 dB to −20 dB (90˜99%), was realized in the frequency range of 1˜12 GHz. This electromagnetic wave absorber is suitable for use in unmanned aerial vehicles (UAVs).

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. An electromagnetic wave absorber, comprising a three-dimensional open-cell type metal porous body, and an electromagnetic wave-absorbing material loaded in pores of the three-dimensional open-cell type metal porous body.

2. The electromagnetic wave absorber as set forth in claim 1, wherein the three-dimensional open-cell type metal porous body has from 5 to 50 pores per inch.

3. The electromagnetic wave absorber as set forth in claim 1, wherein the three-dimensional open-cell type metal porous body comprises one or more non-magnetic metals selected from the group consisting of gold, platinum, silver, copper, nickel, zinc, aluminum, tin, stainless steel and titanium, and alloys thereof.

4. The electromagnetic wave absorber as set forth in claim 1, wherein the three-dimensional open-cell type metal porous body comprises a net laminate obtained by laminating a plurality of nets composed of nonmagnetic metal.

5. The electromagnetic wave absorber as set forth in claim 1, wherein the three-dimensional open-cell type metal porous body comprises any one selected from mats, pads and nonwoven fabrics of nonmagnetic metal fiber.

6. The electromagnetic wave absorber as set forth in claim 1, wherein the three-dimensional open-cell type metal porous body comprises any one selected from the group consisting of mats, pads, and nonwoven fabrics of natural fiber, synthetic fiber, inorganic fiber, ceramic fiber and glass fiber, each of which has a plurality of pores and has a nonmagnetic metal film formed thereon.

7. The electromagnetic wave absorber as set forth in claim 1, wherein the three-dimensional open-cell type metal porous body comprises any one selected from the group consisting of foamed bodies of rubber, natural resin, synthetic resin, ceramic and glass, each of which is coated with a nonmagnetic metal layer.

8. The electromagnetic wave absorber as set forth in claim 1, wherein the electromagnetic wave-absorbing material is formed by dispersing one or more selected from among electromagnetic wave loss materials, including conduction los materials, dielectric loss materials, magnetic loss materials and eddy-current loss materials, in a binder.

9. The electromagnetic wave absorber as set forth in claim 1, wherein the electromagnetic wave-absorbing material is added with an insulator.

10. The electromagnetic wave absorber as set forth in claim 8, wherein the electromagnetic wave loss material is coated with an insulator.

11. The electromagnetic wave absorber as set forth in claim 8, wherein the conduction loss material comprises one or more selected from the group consisting of carbon black, acetylene black, graphite, and silicon carbide powder.

12. The electromagnetic wave absorber as set forth in claim 8, wherein the dielectric loss material comprises one or more selected from the group consisting of alumina-based materials, magnesium titanate-based materials, barium titanate-based materials, lead titanate-based materials, and lithium zirconium titanate-based materials.

13. The electromagnetic wave absorber as set forth in claim 8, wherein the magnetic loss material comprises one or more selected from the group consisting of soft magnetic oxide materials, soft magnetic metal materials and hexagonal magnetic materials.

14. The electromagnetic wave absorber as set forth in claim 8, wherein the eddy-current magnetic material comprises one or more selected from the group consisting of carbonyl iron fiber, carbon fiber and silicon carbide fiber, each of which has an insulator film formed thereon and is powdered.

15. The electromagnetic wave absorber as set forth in claim 8, wherein the eddy-current loss material comprises one or more selected from the group consisting of natural fiber, synthetic fiber, inorganic fiber, glass fiber and ceramic fiber, each of which has a surface having a film of any one selected from the group consisting of tin, aluminum, silver, gold, platinum and copper, formed thereon, and is powdered.

16. The electromagnetic wave absorber as set forth in claim 8, wherein the binder comprises one or more selected from the group consisting of rubber, natural resin, synthetic resin, glass and ceramic.

17. The electromagnetic wave absorber as set forth in claim 1, wherein the electromagnetic wave absorber is formed in any one selected from the group consisting of sheets, panels, and blocks.

18. The electromagnetic wave absorber as set forth in claim 1, further comprising a dielectric layer on at least one surface thereof.

19. A method of constructing an electromagnetic wave absorber, comprising attaching a three-dimensional open-cell type metal porous body to an electromagnetic wave-reflecting surface, and filling pores of the three-dimensional open-cell type metal porous body with an electromagnetic wave-absorbing material using a filler.

20. The method as set forth in claim 19, further comprising forming a dielectric layer on at least one surface of the electromagnetic wave absorber.
